(19) United States
(12) Patent Application Publication
(10) Pub. No.: US 2026/0153675 A1
(43) Pub. Date: Jun. 4, 2026

(54) PACKAGE AND METHODS OF FORMING THE SAME

(71) Applicant: TAIWAN SEMICONDUCTOR MANUFACTURING COMPANY, LTD., Hsinchu (TW)

(72) Inventors: Tzu Jung TIEN, Hsinchu (TW); Jen-Yuan CHANG, Hsinchu (TW)

(21) Appl. No.: 18/963,861

(22) Filed: Nov. 29, 2024

(51) Int. Cl. G02B 6/124; G02B 6/12; G02B 6/13; H01L 23/00; H01L 25/16; H01L 27/146

(52) U.S. Cl. CPC G02B 6/124; G02B 6/13; H10F 39/024; H10F 39/806; H10W 90/00; G02B 2006/12107; H10W 90/792

(57) ABSTRACT

Embodiments of the present disclosure illustrates a package. The package includes a photonic die including: a waveguide, a first grating coupler, and a second grating coupler disposed in a cladding layer. The first grating coupler and the second grating coupler have a gap therebetween in a first direction, wherein the first grating coupler has a first end and a second end in a second direction perpendicular to the first direction. The photonic die also includes a first optical guard structure through the cladding layer, disposed in the gap, and extending over the first end and the second end of the first grating coupler in the second direction. The package also includes an interconnect structure disposed in a first dielectric layer and a second dielectric layer over the cladding layer, an electronic die including circuits electrically coupled to the interconnect structure, and an insulating layer laterally surrounding the electronic die.

### BACKGROUND

Electrical signaling and processing are one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIGS. 1 to 5, 7, and 9 to 11 illustrate cross-sectional views of intermediate steps of forming a photonic package, in accordance with some embodiments.

FIGS. 6A to 6L illustrate plan views of optical guard structures and grating couplers, in accordance with some embodiments.

FIGS. 8A and 8B illustrate a cross-sectional view and a plan view of optical guard structures and grating couplers, in accordance with some embodiments.

FIG. 12 illustrates a cross-sectional view of an intermediate step of a photonic package, in accordance with some embodiments.

FIG. 13 illustrates a cross-sectional view of an intermediate step of a photonic package, in accordance with some embodiments.

FIG. 14 illustrates a cross-sectional view of an intermediate step of a photonic package, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly.

In this disclosure, various aspects of a package and the formation thereof are described. A package including both optical devices and electrical devices, and the method of forming the same are provided, in accordance with some embodiments. In particular, the photonic package may include grating couplers as an interface to send or receive optical signals to or from an external photonic device. This disclosure provides an optical guard structure that may be disposed around the light paths directing to the grating couplers, which may effectively reduce the interference between optical signals. Thus, the photonic package may include an increased density of the grating couplers with reduced optical signal transmission noise. The intermediate stages of forming the packages are illustrated, in accordance with some embodiments. Some variations of some embodiments are discussed. Throughout the various views and illustrative embodiments, like reference numbers are used to designate like elements.

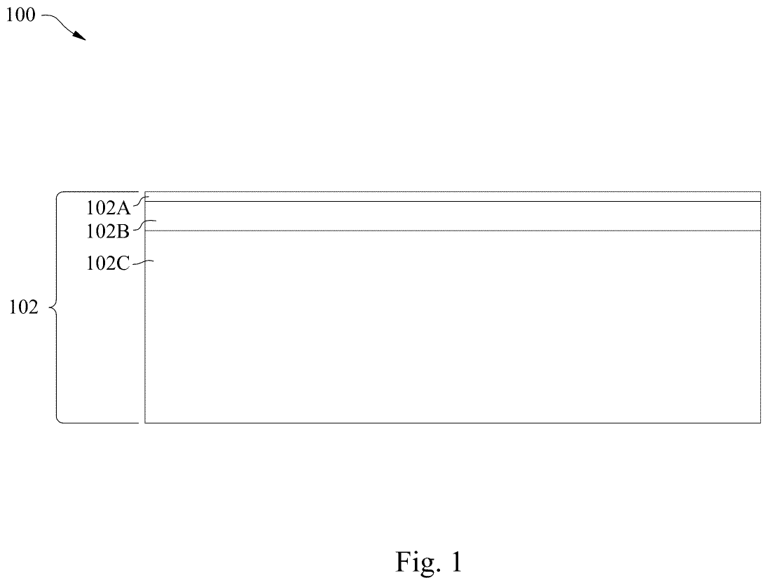

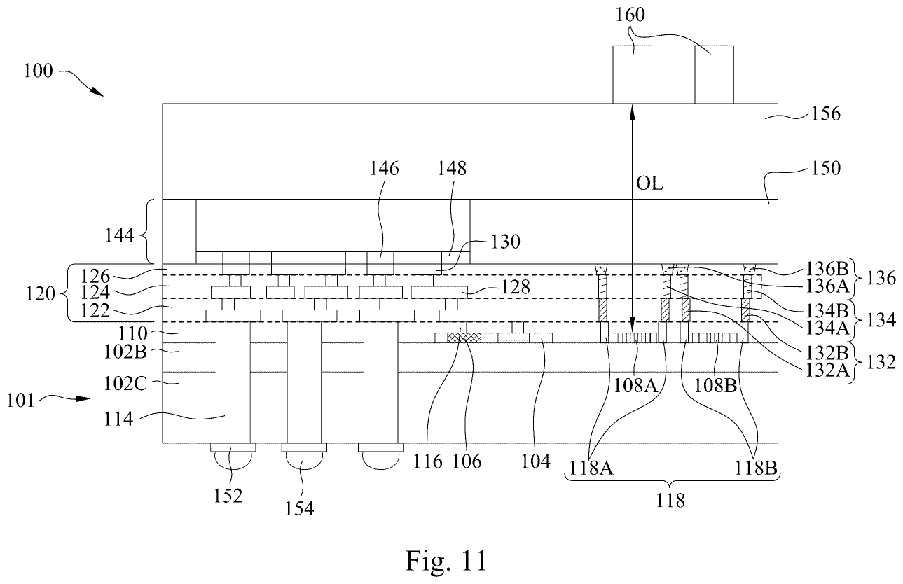

FIGS. 1 to 5, 7 and 9 to 11 illustrate cross-sectional views of intermediate steps of forming a photonic package 100 (see FIG. 11), in accordance with some embodiments. The photonic package 100 may be part of a computing system. FIGS. 1 to 8B may illustrate the formation of a photonic die 101. In some embodiments, the photonic package 100 provides an input/output (I/O) interface between optical signals and electrical signals in a computing system. In some embodiments, the photonic package 100 provides an optical network for signal communication between components (e.g., photonic devices, integrated circuits, couplings to external fibers, etc.) within the photonic package 100.

Turning first to FIG. 1, a substrate 102 is provided, in accordance with some embodiments. The substrate 102 may include a device layer 102A, an insulating layer 102B, and a bulk substrate 102C. The device layer 102A may be disposed over an insulating layer 102B, and the insulating layer 102B may be disposed over a bulk substrate 102C. In some embodiments, the device layer 102A may include silicon, silicon compound such as silicon germanium, silicon nitride, or other suitable materials that are suitable for forming photonic devices. In an embodiment, the insulating layer 102B includes an oxide such as silicon oxide or other suitable dielectric material. The device layer 102A has a thickness from about 0.1 μm to about 1.5 μm, and the insulating layer 102B has a thickness from about 0.5 μm to about 4μm in some embodiments. Other thicknesses are possible. The bulk substrate 102C may be, for example, a material such as a glass, ceramic, dielectric, a semiconductor, the like, or a combination thereof. The bulk substrate 102C may be a wafer, such as a silicon wafer, and the photonic package 100 may be diced in manufacturing steps later. In some embodiments, the bulk substrate 102C is a semiconductor substrate, which is doped (e.g., with a p-type or an n-type dopant) or undoped. For example, the semiconductor material of the bulk substrate 102C may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The bulk substrate 102C may include a multi-layered composition or a gradient composition. In some embodiments, the substrate 102 is a buried oxide (“BOX”) substrate. The BOX substrate includes a buried oxide layer 102B disposed over a silicon substrate 102C, and a device layer 102A disposed over the buried oxide layer 102B.

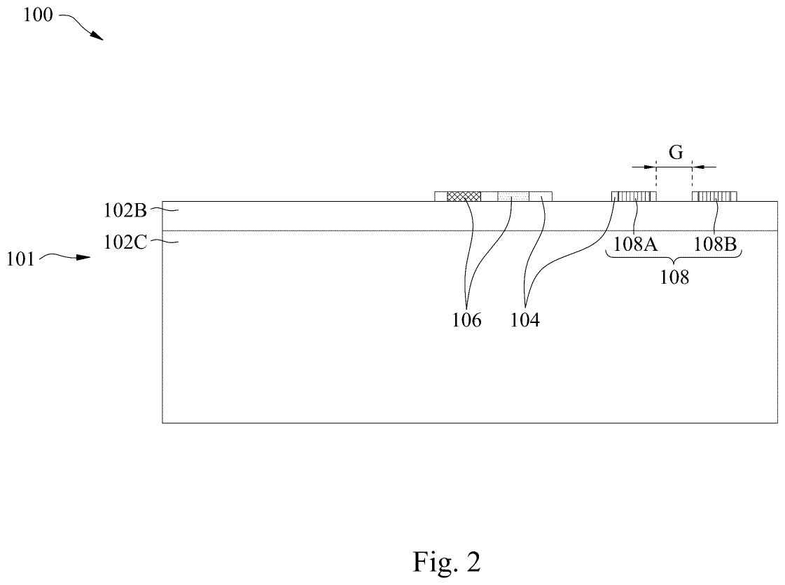

In FIG. 2, the device layer 102A is patterned to form waveguides 104, photonic components 106, and grating couplers 108, in accordance with some embodiments. In some embodiments, other types of couplers (not individually labeled in the Figures) may be formed in the device layer 102A. The device layer 102A may be patterned using suitable photolithography and etching techniques. For example, a hard mask layer (e.g., a nitride layer or other dielectric material, not shown in FIG. 2) may be formed over the device layer 102A and patterned, in some embodiments. The pattern of the hard mask layer may then be transferred to the device layer 102A using an etching process. The etching process may include, for example, a dry etching process and/or a wet etching process. For example, the device layer 102A may be etched to form recesses defining the waveguides 104, with sidewalls of the remaining unrecessed portions defining sidewalls of the waveguides 104. In some embodiments, more than one photolithography and etching sequence may be used in order to pattern the device layer 102A. One waveguide 104 or multiple waveguides 104 may be patterned from the device layer 102A. If multiple waveguides 104 are formed, the multiple waveguides 104 may be individual separate waveguides 104 or connected as a single continuous structure. In some embodiments, one or more of the waveguides 104 form a continuous loop.

The photonic components 106 may be integrated with the waveguides 104, and may be formed with the silicon waveguides 104. The photonic components 106 may be optically coupled to the waveguides 104 to interact with optical signals within the waveguides 104. The photonic components 106 may include, for example, photonic devices such as photodetectors and/or modulators. For example, a photodetector may be optically coupled to the waveguides 104 to detect optical signals within the waveguides 104 and generate electrical signals corresponding to the optical signals. A modulator may be optically coupled to the waveguides 104 to receive electrical signals and generate corresponding optical signals within the waveguides 104 by modulating optical power within the waveguides 104. In this manner, the photonic components 106 facilitate the input/output (I/O) of optical signals to and from the waveguides 104. In other embodiments, the photonic components may include other active or passive components, such as laser diodes, optical signal splitters, or other types of photonic structures or devices. Optical power may be provided to the waveguides 104 by, for example, to an external photonic component 160, or the optical power may be generated by a photonic component within the photonic package 100 such as a laser diode (not shown).

In some embodiments, the photodetectors may be formed by, for example, partially etching regions of the waveguides 104 and growing an epitaxial material on the remaining silicon of the etched regions. The waveguides 104 may be etched using acceptable photolithography and etching techniques. The epitaxial material may comprise, for example, a semiconductor material such as germanium, which may be doped or undoped. In some embodiments, an implantation process may be performed to introduce dopants within the silicon of the etched regions as part of the formation of the photodetectors. The silicon of the etched regions may be doped with p-type dopants, n-type dopants, or a combination. In some embodiments, the modulators may be formed by, for example, partially etching regions of the waveguides 104 and then implanting appropriate dopants within the remaining silicon of the etched regions. The waveguides 104 may be etched using acceptable photolithography and etching techniques. In some embodiments, the etched regions used for the photodetectors and the etched regions used for the modulators may be formed using one or more of the same photolithography or etching steps. The silicon of the etched regions may be doped with p-type dopants, n-type dopants, or a combination. In some embodiments, the etched regions used for the photodetectors and the etched regions used for the modulators may be implanted using one or more of the same implantation steps.

In some embodiments, a plurality of grating couplers 108 are integrated with the waveguides 104. Although only first grating couplers 108A and second grating coupler 108B are illustrated in FIG. 2, more grating couplers 108 may be used. For example, the grating couplers may be arranged as a matrix in a plan view. In other words, more grating couplers may be arranged in the cross-section as illustrated in FIG. 2 and/or in a direction perpendicular to the cross-section as illustrated in FIG. 2. The grating couplers 108 are photonic structures that allow optical signals and/or optical power to be transferred between the photonic devices in the device layer 102A (e.g., waveguides 104 and/or photonic components 106) and a photonic device disposed outside the device layer 102A. The grating couplers 108 may be formed using acceptable photolithography and etching techniques. In an embodiment, the grating couplers 108 are formed after the waveguides 104 are defined. For example, a photoresist may be formed on the waveguides 104 and the device layer 102A. The photoresist may be patterned with openings corresponding to the grating couplers 108. One or more etching processes may be performed using the patterned photoresist as an etching mask to form recesses in the waveguides 104 that define the grating couplers 108. The etching processes may include one or more dry etching processes and/or wet etching processes. The above photonic devices are considered within the scope of the present disclosure. Other configurations or arrangements of waveguides 104, the photonic components 106, the grating couplers 108, and/or other couplers are possible, and other types of photonic components 106 may be formed. In some embodiments, the first grating coupler 108A and the second grating coupler 108B have a gap G of about 0.5 mm or less, although a gap larger than about 0.5 mm can be implemented too. However, it is found that the adjacent grating couplers 108 (e.g., the first grating coupler 108A and the second grating coupler 108B) may encounter problems of optical interference when the adjacent grating couplers 108 are too close (e.g., the gap G less than about 0.5 mm).

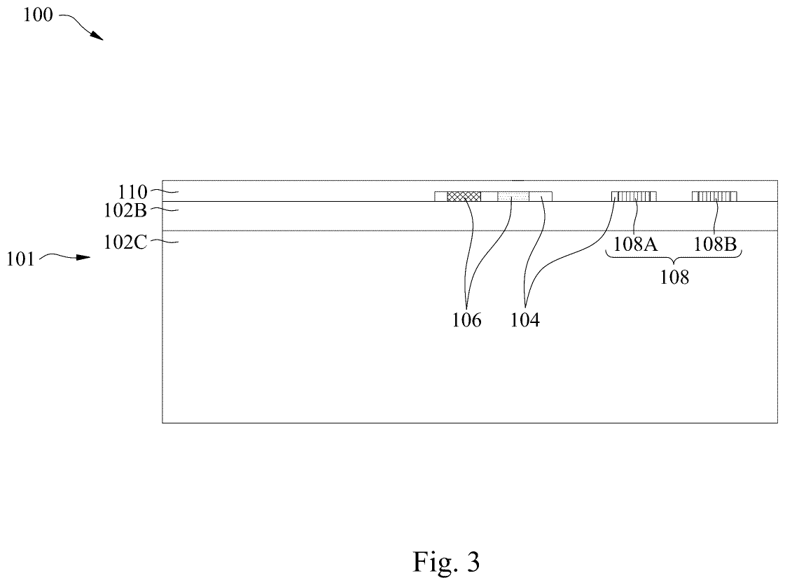

Referring still to FIG. 3, a cladding layer 110 is formed on the front side of the substrate 102, in accordance with some embodiments. The cladding layer 110 may cover the waveguides 104, the photonic components 106, the grating couplers 108, and the insulating layer 102B. The cladding layer 110 may be formed of one or more layers of silicon oxide, silicon nitride, a combination thereof, or the like, and may be formed by CVD, PVD, atomic layer deposition (ALD), a spin-on-dielectric process, the like, or a combination thereof. In some embodiments, the cladding layer 110 is formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other dielectric materials formed by any acceptable process may be used. In some embodiments, the cladding layer 110 is planarized using a planarization process such as a chemical mechanical polishing (CMP) process, a grinding process, or the like. The cladding layer 110 may be formed having a thickness over the insulating layer 102B such as from about 50 nm to about 500 nm or may be formed having a thickness over the waveguides 104 such as from about 10 nm to about 200 nm.

Due to the difference in refractive indices of the materials of the waveguides 104 and the cladding layer 110, the waveguides 104 have high internal reflections such that light is substantially confined within the waveguides 104, depending on the wavelength of the light and the refractive indices of the respective materials. In an embodiment, the refractive index of the material of the waveguides 104 is higher than the refractive index of the material of the cladding layer 110. For example, the cladding layer 110 may be silicon oxide and/or silicon nitride when the waveguides 104 are silicon.

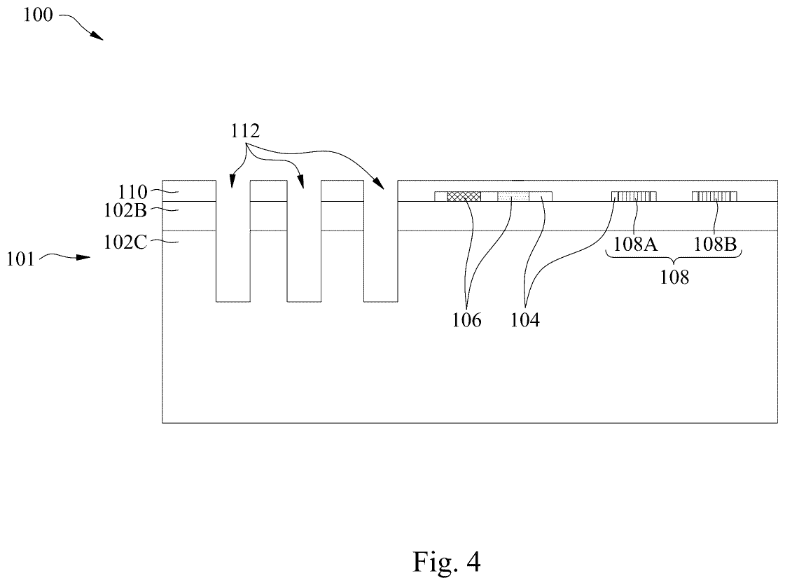

In FIG. 4, openings 112 are formed extending into the bulk substrate 102C, in accordance with some embodiments. The openings 112 are formed extending through the cladding layer 110 and the insulating layer 102B. The openings 112 also extend partially into the bulk substrate 102C. The openings 112 may be formed by acceptable photolithography and etching techniques, such as by forming and patterning a photoresist and then performing an etching process using the patterned photoresist as an etching mask. The etching process may include, for example, a dry etching process and/or a wet etching process.

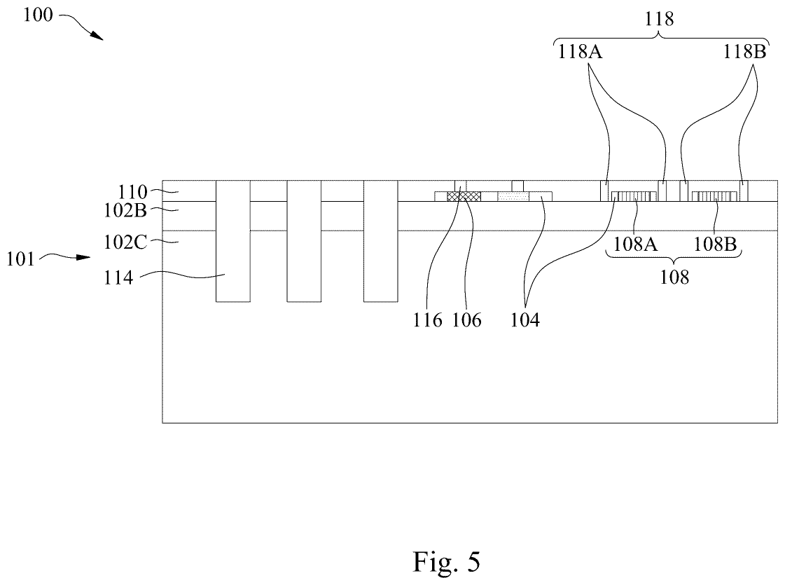

In FIG. 5, a conductive material is formed in the openings 112, thereby forming conductive vias 114 extending into the bulk substrate 102C, in accordance with some embodiments. In some embodiments, a liner (not shown), such as a diffusion barrier layer, an adhesion layer, or the like, may be formed in the openings 112, and may be formed using suitable a deposition process such as CVD, ALD or the like. The liner may include TaN, Ta, TiN, Ti, CoW, a combination thereof, or the like. In some embodiments, a seed layer (not shown), which may include titanium, copper, an alloy thereof, or a combination thereof may then be deposited in the openings 112. The conductive material of the conductive vias 114 in the openings 112 is formed using, for example, electro-chemical plating (ECP), electro-less plating, PCVD, CVD, or other suitable methods. The conductive material may include a metal or a metal alloy of copper, silver, gold, tungsten, cobalt, aluminum. A planarization process (e.g., a CMP process or a grinding process) may be performed to remove excess conductive material along the top surface of the cladding layer 110, such that top surfaces of the conductive vias 114 and the cladding layer 110 are level with each other.

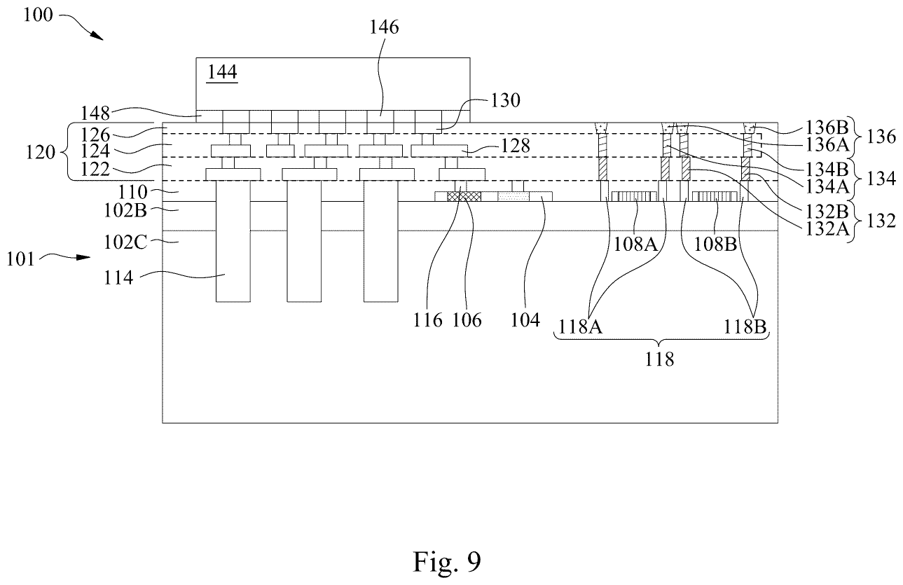

FIG. 5 also shows the formation of contacts 116 that extend through the cladding layer 110 and are electrically connected to the photonic components 106. The contacts 116 (also referred to as a through via) allow electrical power or electrical signals to be transmitted to the photonic components 106 and electrical signals to be transmitted from the photonic components 106. In this manner, the photonic components 106 may convert electrical signals (e.g., from an electronic die 144, see FIG. 9) into optical signals transmitted by the waveguides 104, and/or convert optical signals from the waveguides 104 and the grating couplers 108 into electrical signals (e.g., that may be received by an electronic die 144). The contacts 116 may be formed before or after formation of the conductive vias 114, and the formation of the contacts 116 and the formation of the conductive vias 114 may share some steps such as deposition of the conductive material and/or planarization. In some embodiments, the contact may be formed by a damascene process, e.g., single damascene, dual damascene, or the like. For example, in some embodiments, openings (not shown) for the contacts 116 are first formed in the cladding layer 110 using acceptable photolithography and etching techniques. A conductive material may then be formed in the openings, forming the contacts 116. Excess conductive material may be removed using a CMP process or the like. The conductive material of the contacts 116 may be formed of a metal or a metal alloy including aluminum, copper, tungsten, or the like, which may be the same as that of the conductive vias 114. The contacts 116 may be formed using other techniques or materials in other embodiments.

In FIG. 5, a first optical guard structure 118 is formed in the cladding layer 110, in accordance with some embodiments. The first optical guard structure 118 may include a first optical isolation 118A and a second optical isolation 118B. The first optical guard structure 118 may have a pattern that can substantially block the optical interference, such as reducing the noise from non-vertical or lateral light, and therefore allow the first grating coupler 108A and the second grating coupler 108B to receive optical signals with reduced noise even when they are close. The first optical guard structure 118 may be through vias. For example, the first optical guard structure 118 may be formed by damascene processes described in forming the conductive vias 114 or the contacts 116. The first optical guard structure 118 may be formed before or after formation of the contacts 116 and/or the conductive vias 114, and the formation of the contacts 116 and/or the conductive vias 114 may share some steps such as deposition of the conductive material and/or planarization.

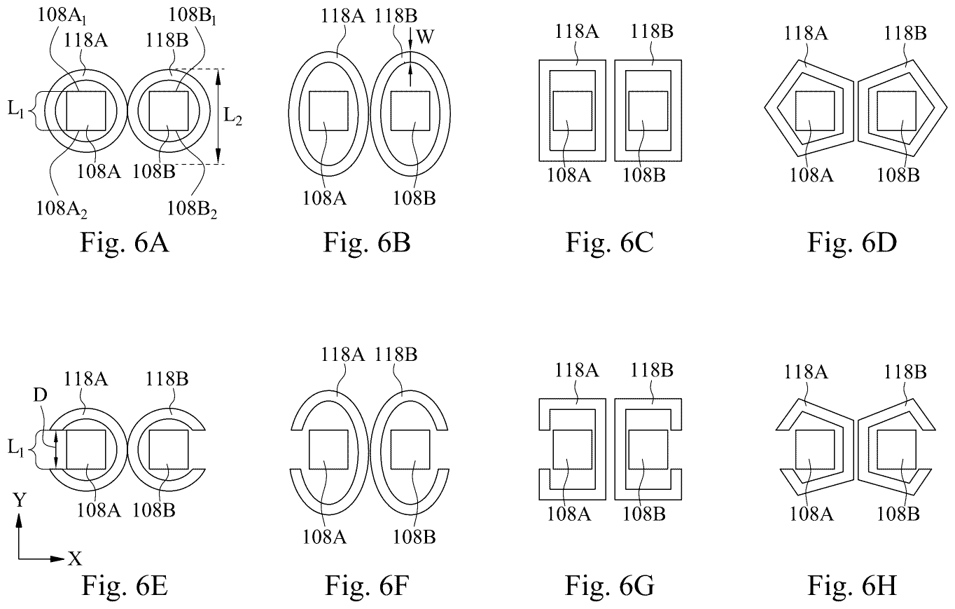

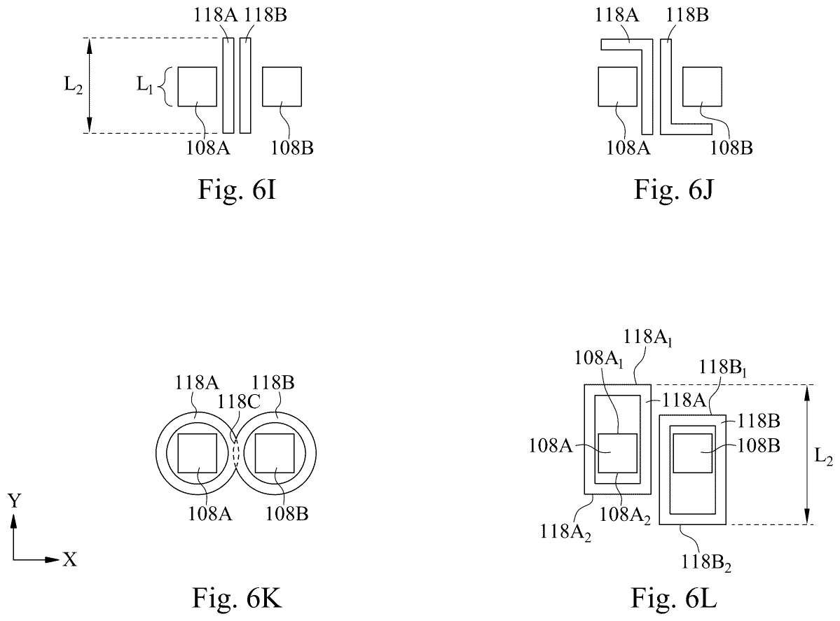

FIGS. 6A to 6L show the exemplary patterns of the first optical guard structure 118 in a plan view. The first grating coupler 108A and the second grating coupler 108B may have the gap G in a first direction (e.g., the X-axis as illustrated in FIG. 6A). The first grating coupler 108A and the second grating coupler 108B may have a length L₁ in a second direction (e.g., the Y-axis as illustrated in FIG. 6A) perpendicular to the first direction. For example, the first grating coupler 108A may have a first end 108A₁ and a second end 108A₂ opposite to the first end 108A₁, and the second grating coupler 108B may have a first end 108B₁ and a second end 108B₂ opposite to the first end 108B₁ in the second direction. The first optical guard structure 118 may at least extend over the first end 108A₁ and the second end 108A₂ of the first grating coupler 108A. In some embodiments, the first optical isolation 118A is disposed between the first grating coupler 108A and the second grating coupler 108B and extends over the first end 108A₁ and the second end 108A₂ of the first grating coupler 108A, and the second optical isolation 118B may be disposed between the first grating coupler 108A and the second grating coupler 108B and extends over the first end 108B₁ and the second end 108B₂ of the second grating coupler 108B. In an embodiment, the first optical isolation 118A extends toward the first grating coupler 108A in a portion of the first optical isolation 118A that is beyond the first end 108A₁ and/or the second end 108A₂ of the first grating coupler 108A or beyond the first end 108B₁ and/or the second end 108B₂ of the second grating coupler 108B, and the second optical isolation 118B extends toward the second grating coupler 108B in a portion of the second optical isolation 118B that is beyond the first end 108A₁ and/or the second end 108A₂ of the first grating coupler 108A or beyond the first end 108B₁ and/or the second end 108B₂ of the second grating coupler 108B. In some embodiments, a total length L₂ of the first optical isolation 118A and the second optical isolation 118B in the second direction is at least 2 times (or about 5 times) greater than the length L1 of the first grating coupler 108A in the second direction (or the total length of the first grating coupler 108A and the second grating coupler 108b).

In some embodiments, the first optical isolation 118A and the second optical isolation 118B each has a shape laterally enclosing the first grating coupler 108A and the second grating coupler 108B, respectively. For example, the first optical isolation 118A and the second optical isolation 118B has an enclosed circular shape as illustrated in FIG. 6A, an enclosed oval ring shape as illustrated in FIG. 6B, an enclosed rectangular or an enclosed square shape as illustrated in FIG. 6C, or an enclosed pentagonal shape as illustrated in FIG. 6D. It is appreciated that any type of ring shape or polygon shape can be implemented for the first optical isolation 118A and the second optical isolation 118B. In some embodiments, each of the first optical isolation 118A and the second optical isolation 118B has a width W of about greater 5 angstroms. It is also appreciated that the dimensions and/or shapes of the first optical isolation 118A and the second optical isolation 118B may not be the same.

Although FIGS. 6A to 6D illustrate the first optical isolation 118A and the second optical isolation 118B have the enclosed shape, at least one of the first optical isolation 118A and the second optical isolation 118B has open ends, in accordance with some embodiments. For example, FIGS. 6E to 6H illustrate the first optical isolation 118A and the second optical isolation 118B having shapes corresponding to FIGS. 6A to 6D, respectively, and with open ends. The open ends may be distant away from the adjacent grating couplers. For example, in FIGS. 6E to 6H, the first optical isolation 118A has open ends distant away from the second grating coupler 108B, and the second optical isolation 118B has open ends distant away from the first grating coupler 108A. The distance D between the open ends of the first optical isolation 118A and the second optical isolation 118B may be varied. In some embodiments, a distance D between the open ends of the first optical isolation 118A or the second optical isolation 118B is smaller than the length L₁ of the first grating coupler 108A or the second grating coupler 108B, although the distance D can be also greater than the length L₁ of the first grating coupler 108A or the second grating coupler 108B.

In some embodiments, as illustrated in FIGS. 6I and 6J, at least one of the first optical isolation 118A and the second optical isolation 118B is a linear wall. The linear wall may have a total length L₂ at least 2 times (or 5 times) greater than the length L₁ of the first grating coupler 108A or the second grating coupler 108B for sufficient blocking the interference between adjacent optical signals that direct to the first grating coupler 108A and the second grating coupler 108B, respectively. As illustrated in FIG. 6I, the linear walls of the first optical isolation 118A or the second optical isolation 118B may only extend in one direction and between the first grating coupler 108A and the second grating coupler 108B. Alternatively, the linear walls may also extend to other directions to block the optical interference from different directions. For example, as shown in FIG. 6J, the first optical guard structure 118A may extend to over an upper side of the first grating coupler 108A, and the second optical guard structure 118B may extend to below a lower side of the second grating coupler 108B.

The first optical isolation 118A and the second optical isolation 118B may be separated from each other or connected. For example, in some embodiments, the first optical isolation 118A and the second optical isolation 118B are connected and have a shared portion. Referring to FIG. 6K as an example, the first optical isolation 118A and the second optical isolation 118B each has a circular shape and have a shared portion 118C. In some embodiments, the first optical isolation 118A and the second optical isolation 118B can be misaligned in the second direction e.g., Y-axis as illustrated in FIG. 6L. For example, as illustrated in FIG. 6L, a first end 118A₁ of the first optical isolation 118A on a first side 108A₁ of the first grating coupler 108A is more distant away than a first end 118B₁ of the second optical isolation 118B on the first side 108A₁ of the first grating coupler 108A in the second direction, and a second end 118B₂ of the second optical isolation 118B on a second side 108A₂ of the first grating coupler 108A is more distant away than a second end 118A₂ of the first optical isolation 118A on the second end 108A₂ of the first grating coupler 108A in the second direction. The shapes of the first optical isolation 118A and the second optical isolation 118B are not limited to the exemplary embodiments described above, for example, a combination of any shapes of the first optical isolation 118A or the second optical isolation 118B in the FIGS. 6A to 6L and or suitable variations based on FIGS. 6A to 6L may be implemented.

In some embodiments, the first optical guard structure 118 is or includes a non-transparent material, such as a metal material, including Cu, Ti, Al, Ag, Au, Cr, W, a combination thereof, or the like, or a compound such as TiN, TaN, WN, a combination thereof, or the like. In some embodiments, the first optical guard structure 118 is or includes a dielectric material with a sufficient refractive index difference with the material of the cladding layer 110 (e.g., first optical guard structure 118 is SiN when the cladding layer 110 is SiO).

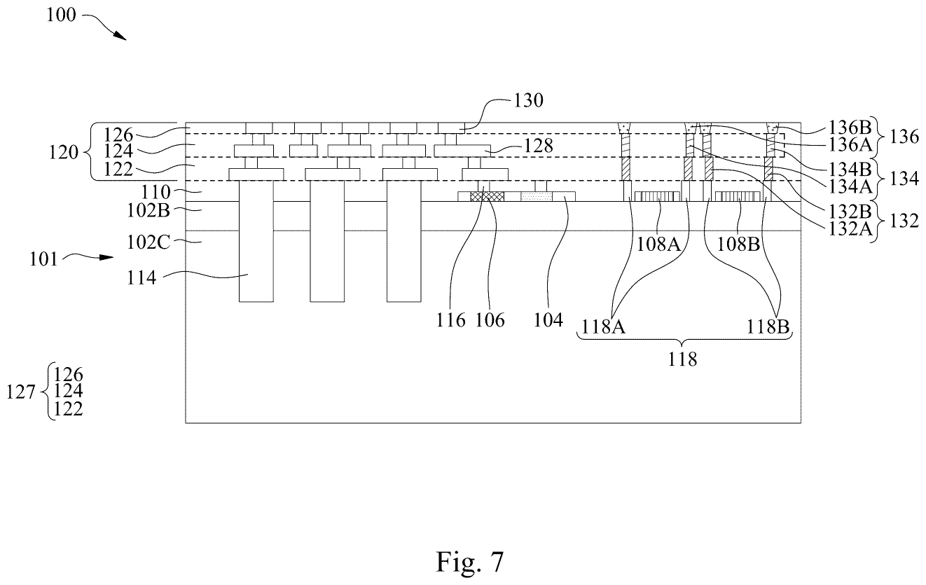

In FIG. 7, an interconnect structure 120 is formed over the device layer 102A, the cladding layer 110, and the contacts 116, in accordance with some embodiments. The interconnect structure 120 includes a first dielectric layer 122, a second dielectric layer 124, and a third dielectric layer 126 (collectively referred to as dielectric layers 127) and an interconnect 128 formed in the dielectric layers 127 that provides electrical interconnections. For example, the interconnect structure 120 may electrically connect the conductive vias 114, the contacts 130, and/or overlying devices such as an electronic die 144 (see FIG. 9). The dielectric layers 127 may be, for example, insulating or passivating layers, and may comprise one or more transparent dielectric materials, such as silicon oxide, silicon nitride, silicon oxynitride, a low-k material (e.g., dielectric constant lower than 3.5) or those described above for the cladding layer 110. The third dielectric layer 126 may be the topmost dielectric layer of the interconnect structure 120 and also referred to as a bonding layer. In some embodiments, the dielectric layers 127 are transparent about the same wavelengths of light as the cladding layer 110. The dielectric layers 127 may be formed using a technique similar to those described above for the cladding layer 110 or using a different technique. The interconnect 128 may include conductive lines and vias, and may be formed by a damascene process, e.g., single damascene, dual damascene, or the like. As shown in FIG. 7, the interconnect 128 also includes conductive pads 130 that are formed in the topmost layer of the dielectric layers 127 (e.g., the third dielectric layer 126). A planarization process (e.g., a CMP process or the like) may be performed after forming the conductive pads 130 such that surfaces of the conductive pads 130 and the third dielectric layer 126 are substantially coplanar. The interconnect structure 120 may include more or fewer dielectric layers 127, interconnect 128, or conductive pads 130 than shown in FIG. 7.

It should be appreciated that the interconnect structure 120 may include any number of dielectric layers and metallization patterns. If more dielectric layers and metallization patterns are to be formed, steps and processes similar to those discussed above may be repeated. The metallization patterns may include conductive lines and conductive vias. The conductive vias may be formed during the formation of the metallization pattern by forming the seed layer and conductive material of the metallization pattern in the opening of the underlying dielectric layer. The conductive vias may therefore interconnect and electrically couple the various conductive lines.

In some embodiments, some regions of the interconnect structure 120 are substantially free of the interconnect 128, conductive pads 130 (referred to as optical regions hereinafter) or any features for electrical transmission purposes, to allow transmission of optical power or optical signals through the dielectric layers 127. For example, transparent regions may extend between the grating couplers 108 and the external photonic components 160 (see FIG. 11) to allow optical power or optical signals to be coupled from the waveguides 104 into the external photonic components 160 and/or to be coupled from the external photonic components 160 into the waveguides 104. In some cases, a thinner interconnect structure 120 may allow for more efficient optical coupling between the grating couplers 108 and the external photonic components 160.

In some embodiments, the interconnect structure 120 also includes a second optical guard structure 132 disposed in the first dielectric layer 122, a third optical guard structure 134 disposed in the second dielectric layer 124, and a fourth optical guard structure 136 disposed in the third dielectric layer 126. In some embodiments, the second optical guard structure 132, the third optical guard structure 134, and the fourth optical guard structure 136 each includes a plurality of optical isolations. For example, the second optical guard structure 132 may include a first optical isolation 132A over the first optical isolation 118A of the first optical guard structure 118 and a second optical isolation 132B over the second optical isolation 118B of the first optical guard structure 118. The third optical guard structure 134 may include a first optical isolation 134A over the first optical isolation 132A of the second optical guard structure 132 and a second optical isolation 134B over the second optical isolation 132B of the second optical guard structure 132. The fourth optical guard structure 136 may include a first optical isolation 136A over the first optical isolation 134A of the third optical guard structure 134 and a second optical isolation 136B over the second optical isolation 134B of the third optical guard structure 134. Each of the second optical guard structure 132, the third optical guard structure 134, and the fourth optical guard structure 136 may have a pattern similar or corresponding to the first optical guard structure 118, such as having the shapes as illustrated in FIGS. 6A to 6L. In some embodiments, the second optical guard structure 132, the third optical guard structure 134, and the fourth optical guard structure 136 have different sizes. For example, the fourth optical guard structure 136 may have a size greater than the third optical guard structure 134, and the third optical guard structure 134 may have a size greater than the second optical guard structure 132, wherein the second optical guard structure 132 has a size greater than the first optical guard structure 118.

In some embodiments, the second to fourth optical guard structures 132 to 136 are manufactured in same processes of forming the interconnect 128. The second to fourth optical guard structures 132 to 136 may have a same material as the materials of the interconnect 128. In some embodiments, the second to fourth optical guard structures 132 to 136 are formed in processes different from the processes of forming the interconnect 128 although some processes such as planarization processes can be shared. In such embodiments, the second to fourth optical guard structures 132 to 136 may have a different material form the interconnect 128.

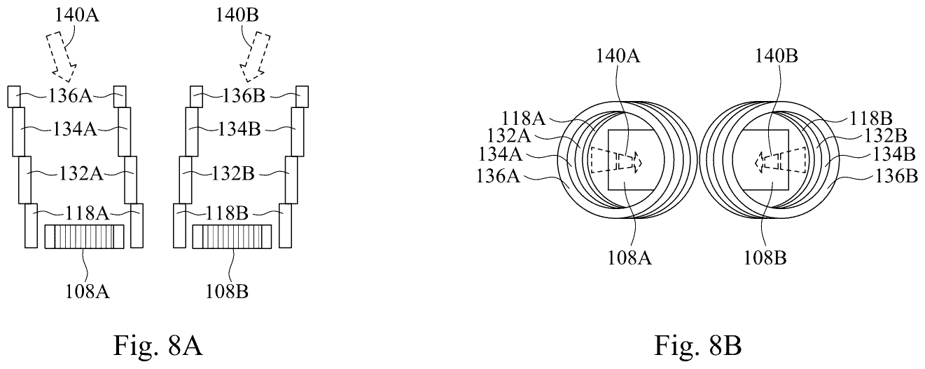

In some embodiments, as illustrated in FIG. 8A, the first optical isolations 118A, 132A, 134A, and 136A of the first to fourth optical guard structures 118, 132, 134, and 136 gradually shift away the second grating coupler 108B from a lower level to a higher level. In some embodiments, the second optical isolations 118B, 132B, 134B, and 136B of the first to fourth optical guard structures 118, 132, 134, and 136 gradually shift away from the first grating coupler 108A from a lower level to a higher level. In such embodiments, in a plan view as illustrated in 8B, the first optical isolations 118A, 132A, 134A, and 136A of the first to fourth optical guard structures 118, 132, 134, and 136 may form a continuous structure and accommodate a first light path 140A directing to the first grating coupler 108A in a non-vertical direction. The second optical isolations 118B, 132B, 134B, and 136B of the first to fourth optical guard structures 118, 132, 134, and 136 may also form a continuous structure and accommodate a second light path 140B directing to the second grating coupler 108B in a non-vertical direction. The first light path 140A and the second light path 140B may be more distant away from a lower level to a higher level. As such, the first and second light paths 140A and 140B to the first grating coupler 108A and the second grating coupler 108B can be more effectively separated and thus reduce optical interference between adjacent optical signals that direct to the first grating coupler 108A and the second grating coupler 108B, respectively. The first optical isolations 118A, 132A, 134A, and 136A of the first to fourth optical guard structures 118, 132, 134, and 136 and/or the second optical isolations 118B, 132B, 134B, and 136B of the first to fourth optical guard structures 118, 132, 134, and 136 may not only gradually shift in directions as illustrated in FIG. 8B and can gradually shift toward any direction for collecting the lights from the external photonic components 160.

In some embodiments, the materials of the second to fourth optical guard structures 132 to 136 are or include a non-transparent material, such as a metal material, including Cu, Ti, Al, Ag, Au, Cr, W, a combination thereof, or the like, or a compound such as TiN, TaN, WN, a combination thereof, or the like. In some embodiments, second to fourth optical guard structures 132 to 136 are or includes a dielectric material that have a sufficient refractive index difference with the material of the dielectric layers 127 (e.g., second to fourth optical guard structures 132 to 136 are SiN when the cladding layer 110 is SiO).

In FIG. 9, an electronic die 144 is bonded to the interconnect structure 120, in accordance with some embodiments. The electronic die 144 may be, for example, semiconductor devices, dies, or chips that communicate with the photonic components 106 using electrical signals. One electronic die 144 is shown in FIG. 9, but the photonic package 100 may include two or more electronic dies 144 in some embodiments. In an embodiment, multiple electronic dies 144 may be incorporated into a single photonic package 100.

The electronic die 144 may include integrated circuits for interfacing with the photonic components, such as circuits for controlling the operation of the photonic components 106. For example, the electronic die 144 may include controllers, drivers, transimpedance amplifiers, the like, or combinations thereof. The electronic die 144 may also include a central processing unit (CPU), in some embodiments. In some embodiments, the electronic die 144 includes circuits for processing electrical signals received from photonic components 106, such as for processing electrical signals received from a photodetector. The electronic die 144 may control high-frequency signaling of the photonic components 106 according to electrical signals (digital or analog) received from another device, such as from a processing die, in some embodiments. In some embodiments, the electronic die 144 may act as part of an I/O interface between optical signals and electrical signals within a photonic system.

The electronic die 144 includes die connectors 146 disposed in a dielectric bonding layer 148. The die connectors 146 may be, for example, conductive pads, conductive pillars, or the like. The dielectric bonding layer 148 may have a material similar to those of the third dielectric layer 126. In some embodiments, the electronic die 144 is bonded to the interconnect structure 120 by dielectric-to-dielectric bonding and/or metal-to-metal bonding. In some embodiments, covalent bonds are formed between the dielectric bonding layer 148 and the third dielectric layer 126. During the bonding, metal bonding may also occur between the die connectors 146 of the electronic die 144 and the conductive pads 130 of the interconnect structure 120. Additionally, by bonding the electronic die 144 to the interconnect structure 120 in this manner, the thickness of the resulting photonic package 100 may be reduced, and the optical coupling between the grating couplers 108 and the external photonic components 160 may be improved.

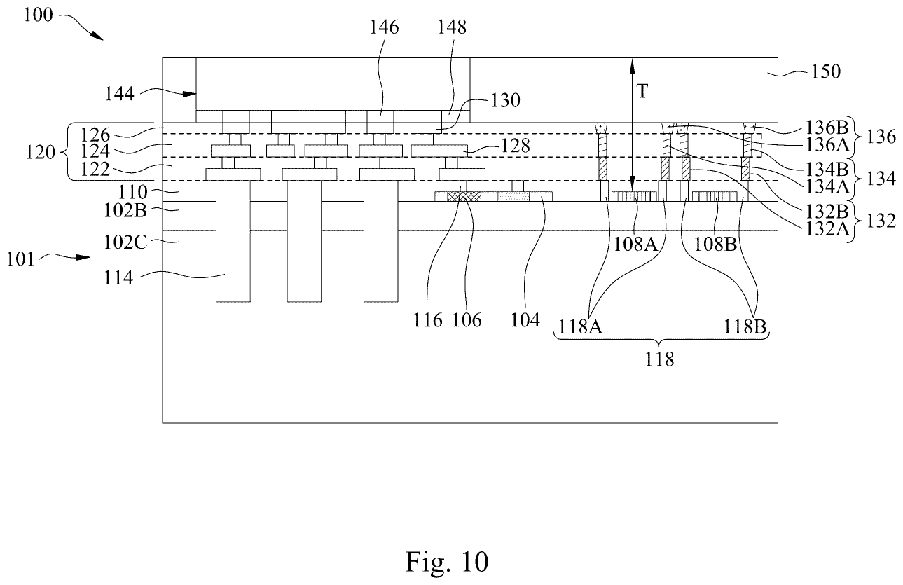

In FIG. 10, an insulating layer 150 is formed adjacent to the electronic die 144 and over the interconnect structure 120, in accordance with some embodiments. The insulating layer 150 may include a transparent dielectric material, such as silicon oxide, silicon nitride, a polymer, the like, or a combination thereof. In some embodiments, the insulating layer 150 may be a material (e.g., silicon oxide) that is substantially transparent to light at wavelengths suitable for transmitting optical signals or optical power between the external photonic components 160 and the grating couplers 108.

The insulating layer 150 may be formed by a suitable deposition method, including CVD, PVD, the like, or a combination thereof. In some embodiments, the insulating layer 150 is formed by HDP-CVD, FCVD, the like, or a combination thereof. In some embodiments, the insulating layer 150 covers the electronic die 144 and fills the gap adjacent to the electronic die 144 after the deposition. A planarization process such as a CMP process, a grinding process, or the like may then be performed. In an embodiment, the top surface of the electronic die 144 is exposed from the insulating layer 150 and coplanar with a top surface of the insulating layer 150. In some embodiments, the insulating layer 150 covers the top surface of the electronic die 144 and has a planarized top surface. In some embodiments, the combined thickness T of the cladding layer 110, the dielectric layers 127, and the insulating layer 150 over the grating couplers 108 is between about 10 μm and about 50 μm. In some embodiments, the thickness T may be less than about 30 μm.

In FIG. 11, a supporting substrate 156 is attached to the insulating layer 150, in accordance with some embodiments. The supporting substrate 156 is a rigid structure that is attached to the structure in order to provide structural or mechanical stability. The use of a supporting substrate 156 can reduce warping or bending, which can improve the performance of the optical structures such as the waveguides 104 or photonic components 106. The supporting substrate 156 may comprise one or more materials such as silicon (e.g., a silicon wafer, bulk silicon, or the like), a silicon oxide, a metal, an organic core material, the like, or another type of material. The supporting substrate 156 may be attached to the structure (e.g., to the insulating layer 150 and/or the electronic die 144) using an adhesive layer, or the supporting substrate 156 may be attached using direct bonding or another suitable technique. In some embodiments, the supporting substrate 156 may have a thickness between about between about 500 μm and about 700 μm. The supporting substrate 156 may also have lateral dimensions (e.g., length, width, and/or area) that are greater than, about the same as, or smaller than the substrate 102. In some embodiments, the supporting substrate 156 is attached at a later process step during the manufacturing the photonic package 100 than shown. The supporting substrate 156 may be removed after forming the conductive connectors 154 or at other manufacturing steps later for some embodiments that the photonic package 100 has the needs to be thin. In some embodiments, the supporting substrate 156 is not removed for providing to reduce warping or bending of the photonic package 100.

External photonic components 160 may be disposed over the supporting substrate 156 (or over the insulating layer 150 if the supporting substrate 156 is not present). The external photonic components 160, such as optical fibers or lens, can serve as an optical input/output (I/O) for the photonic package 100. In some embodiments, the first grating coupler 108A may communicate with one of the external photonic components 160 through the first light path 140A, and the second grating coupler 108B may communicate with another one of the external photonic components 160 through the second optical path 140B, wherein lights transmitted in the first light path 140A and the second optical path 140 would not interfere with each other because the optical interference may be effectively reduced or prevented by the optical guard structures. In some embodiments, the first light path 140A or the second light path 140B may have a length OL, which may be the thickness of the supporting substrate 156 plus the combined thickness T or the combined thickness T only (if the supporting substrate 156 is removed later).

Still referring to FIG. 11, the back side of the bulk substrate 102C is thinned to expose the conductive vias 114, and conductive pads 152 are formed, in accordance with some embodiments. The bulk substrate 102C may be thinned by a CMP process, a mechanical grinding, or the like. In FIG. 11, conductive pads 152 are formed on the exposed conductive vias 114 and the bulk substrate 102C, in accordance with some embodiments. The conductive pads 152 are electrically connected to the interconnect structure 120. The conductive pads 152 may be formed from a conductive material such as copper, aluminum, another metal or metal alloy, the like, or combinations thereof. In some embodiments, after the supporting substrate 156 is flipped over, a passivation layer (not shown) such as a silicon oxide or silicon nitride may be formed over the bulk substrate 102C to laterally surround or partially cover the conductive pads 152.

Conductive connectors 154 are formed on conductive pads 152. The conductive connectors 154 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 154 may include a conductive material such as solder, copper, aluminum, gold, nickel, silver, palladium, tin, the like, or a combination thereof. In some embodiments, the conductive connectors 154 are formed by initially forming a layer of solder through such commonly used methods such as evaporation, electroplating, printing, solder transfer, ball placement, or the like. Once a layer of solder has been formed on the structure, a reflow may be performed in order to shape the material into the desired bump shapes. In another embodiment, the conductive connectors 154 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed over the conductive connectors 154. The metal cap layer may include nickel, tin, tin-lead, gold, silver, palladium, indium, nickel-palladium-gold, nickel-gold, the like, or a combination thereof and may be formed by a plating process.

In some embodiments, the photonic package 100 is integrated with other electrical and/or photonic components, other electrical and/or photonic dies, or other electrical and/or photonic packages to form a photonic system. For example, the photonic package 100 may be mounted to an interposer, an organic substrate, or a PCB later by the conductive connectors 154.

With the forming of the first optical guard structure 118 in the cladding layer 110 and/or the second to fourth optical guard structures 132 to 136 in the interconnect structure 120 of the photonic die 101, the optical paths directing to the grating couplers 108 (e.g., the first grating coupler 108A and the second grating coupler 108B) are protected by the optical guard structures. Thus, even when the photonic package 100 continues to shrink and need to use grating couplers 108 that are arranged tightly in a small footprint, the ensued problems of the optical interference can be reduced or resolved. In some embodiments, depending on the design or manufacturing ability or costs, at least one of the first to fourth optical guard structures 118, 132 to 136 can be omitted. For example, when the grating couplers 108 are too close so there are not sufficient room to form the first optical guard structure 118 between the first grating coupler 108A and the second grating coupler 108B, the first optical guard structure 118 may not need to be formed. In such embodiments, the size of the second to fourth optical guard structures 132 to 136 may be reduced to be substantially the same as or smaller than the size of the grating couplers 108, to achieve the desired goal of reducing optical interference. In some embodiments, as will be described below, more optical guard structures can be added to further enhance the performance of the optical guard structures.

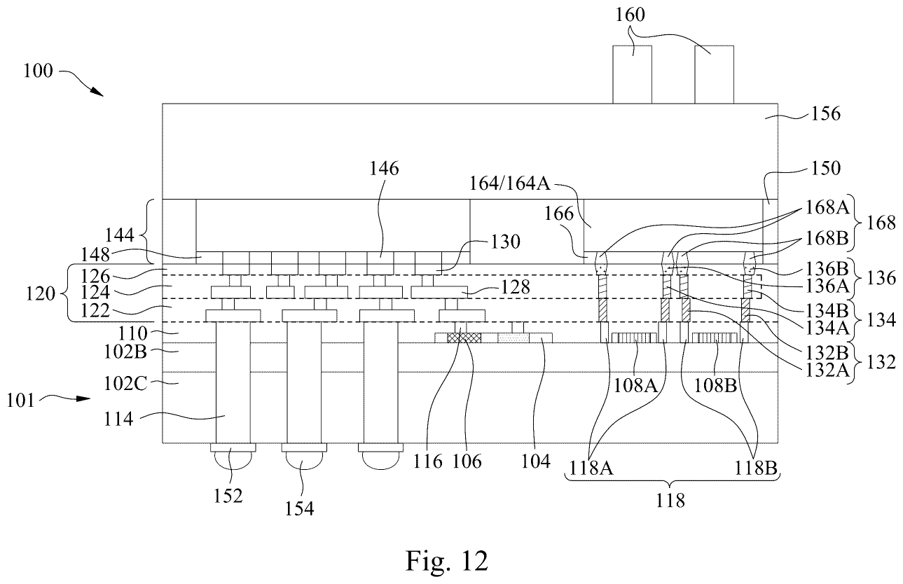

Referring to FIG. 12, in some embodiments, the photonic package 100 further includes at least one dummy die 164. In some embodiments, the dummy die 164 is at least laterally encapsulated by the insulating layer 150 to reduce the amount of insulating layer 150 and help improving coefficient of thermal expansion (CTE) mismatch, which results in warpage of the photonic package 100. In some embodiments, the dummy die 164 may be bonded over the interconnect structure 120 before the insulating layer 150 is provided over the interconnect structure 120. For example, the electronic die 144 and the dummy die 164 may be picked and placed (bonded) onto the interconnect structure 120 at the same step. Then, the insulating layer 150 is provided over the interconnect structure 120 to at least laterally encapsulate the electronic die 144 and the dummy die 164.

In some embodiments, the dummy die 164 includes a substrate 164A and a dielectric bonding layer 166 facing the interconnect structure 120 to allow the dummy die 164 bonded to the third dielectric layer 126 of the interconnect structure 120. In some embodiments, the dielectric bonding layer 166 includes a material similar to those described for the dielectric layers 127, such as silicon oxide. A fifth optical guard structure 168 may be formed in the dielectric bonding layer 166, for example, by a damascene process. The fifth optical guard structure 168 may be disposed over the fourth optical guard structure 136. For example, the fifth optical guard structure 168 may include a first optical isolation 168A disposed over the first optical isolation 136A of the fourth optical guard structure 136 and a second optical isolation 168B disposed over the second optical isolation 136B of the fourth optical guard structure 136. In some embodiments, the first optical isolation 168A and the second optical isolation 168B of the fifth optical guard structure 168 are in contact with the first optical isolation 136A and the second optical isolation 136B of the fourth optical guard structure 136, respectively, thereby forming metal-metal bonds. The fifth optical guard structure 168 may overlap the gap G in the plan view. The fifth optical guard structure 168 may also extend over the first end 108A₁ and the second end 108A₂ of the first grating coupler 108A and/or the first end 108B₁ and the second end 108B₂ of the second grating coupler 108B.

The first optical isolation 168A and the second optical isolation 168B of the fifth optical guard structure 168 may have the shape as illustrated in FIGS. 6A to 6L in a plan view. For example, first optical isolation 168A and the second optical isolation 168B of the fifth optical guard structure 168 may have substantially the same shape as the first optical isolation 136A and the second optical isolation 136B of the fourth optical guard structure 136, respectively. In some embodiments, the first optical isolation 168A and the second optical isolation 168B of the fifth optical guard structure 168 may have a size greater than the first optical isolation 136A and the second optical isolation 136B of the fourth optical guard structure 136, respectively. In such embodiments, the first to fifth optical guard structures 118, 132 to 136, and 168 may form a continuous structure having tapered sidewalls. In some embodiments, the first optical isolation 168A and the second optical isolation 168B of the fifth optical guard structure 168 may be horizontally offset to the first optical isolation 136A and the second optical isolation 136B of the fourth optical guard structure 136 along the shifting directions as illustrated in FIGS. 8A and 8B. In some embodiments, as illustrated in FIG. 12, the first optical isolation 136A and the second optical isolation 136B of the fourth optical isolation 136 have a tapered shape, and the first optical isolation 168A and the second optical isolation 168B of the fifth optical guard structure 168 have a reversed tapered shape. In some embodiments, the fifth optical guard structure 168 are omitted so that no features (except impurities) is disposed in the dielectric bonding layer 166.

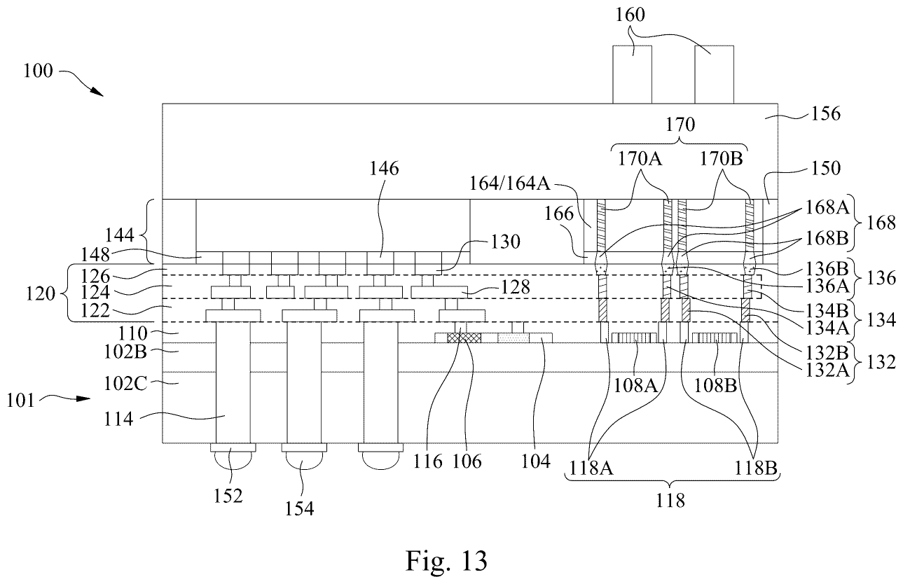

Referring to FIG. 13, the dummy die 164 also includes a sixth optical guard structure 170 disposed in the substrate 164A of the dummy die 164, in accordance with some embodiments. The sixth optical guard structure 170 may include a first optical isolation 170A disposed over the first optical isolation 168A of the fifth optical guard structure 168 and a second optical isolation 170B disposed over the second optical isolation 168B of the fifth optical guard structure 168.

The sixth optical guard structure 170 may overlap the gap G in the plan view. The sixth optical guard structure 170 may also extend over the first end 108A₁ and the second end 108A₂ of the first grating coupler 108A and/or the first end 108B₁ and the second end 108B₂ of the second grating coupler 108B. The first optical isolation 170A and the second optical isolation 170B of the sixth optical guard structure 170 may have the shapes as illustrated in FIGS. 6A to 6L in a plan view. For example, the first optical isolation 170A and the second optical isolation 170B of the sixth optical guard structure 170 may have substantially the same shape as the first optical isolation 168A and the second optical isolation 168B of the fifth optical guard structure 168, respectively. In an embodiment, the first optical isolation 170A and the second optical isolation 170B of the sixth optical guard structure 170 have sizes greater than the first optical isolation 168A and the second optical isolation 168B of the fifth optical guard structure 168, respectively. In such embodiments, the first to sixth optical guard structures 118, 132 to 136, 168, and 170 may form a continuous structure having tapered sidewalls. In some embodiments, the first optical isolation 170A and the second optical isolation 170B of the sixth optical guard structure 170 may be horizontally offset to the first optical isolation 168A and the second optical isolation 168B of the fifth optical guard structure 168 along to the shifting directions as illustrated in FIGS. 8A and 8B. In some embodiments, the sixth optical guard structure 170 are through substrate vias (TSV) and may be formed by any suitable methods for forming the TSVs. As illustrated in FIG. 13, the first optical isolation 170A and the second optical isolation 170B of the sixth optical guard structure 170 have vertical sidewalls. In some embodiments, the sixth optical guard structure 170 have reversed tapered sidewalls. In some embodiments, the sixth optical guard structure 170 are omitted so that no features (except impurities) is disposed in the substrate 164A.

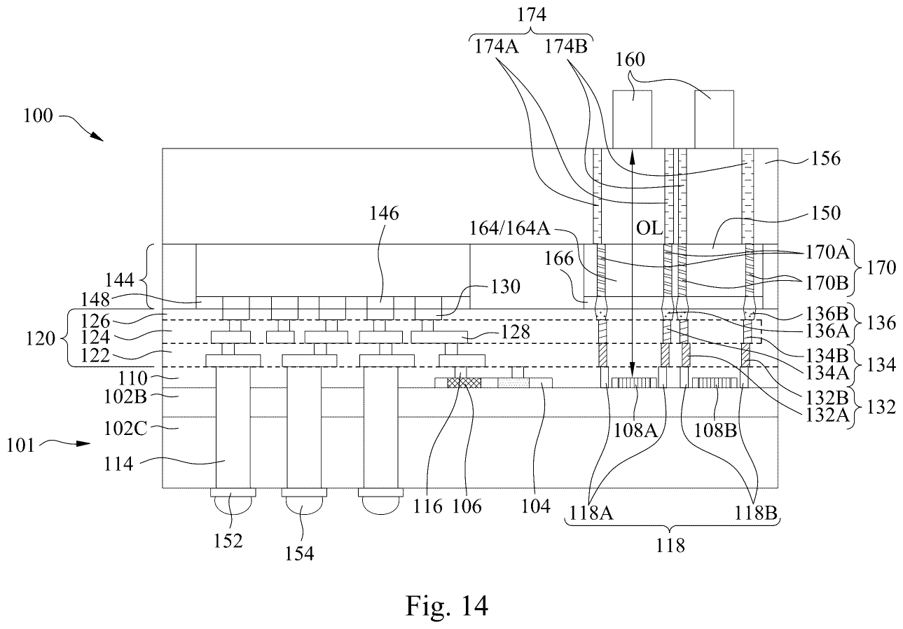

Referring to FIG. 14, the supporting substrate 156 also includes a seventh optical guard structure 174 disposed in the supporting substrate 156, in accordance with some embodiments. The seventh optical guard structure 174 may include a first optical isolation 174A disposed over the first optical isolation 170A of the sixth optical guard structure 170 (or over the first optical isolation of another optical guard structure if the sixth optical guard structure 170 is not present) and a second optical isolation 174B disposed over the second optical isolation 170B of the sixth optical guard structure 170 (or over the second optical isolation of another optical guard structure if the sixth optical guard structure 170 is not present).

The seventh optical guard structure 174 may overlap the gap G in the plan view. The seventh optical guard structure 174 may also extend over the first end 108A₁ and the second end 108A₂ of the first grating coupler 108A and/or the first end 108B₁ and the second end 108B₂ of the second grating coupler 108B. The first optical isolation 174A and the second optical isolation 174B of the seventh optical guard structure 174 may have the shapes as illustrated in FIGS. 6A to 6L in a plan view. For example, the first optical isolation 174A and the second optical isolation 174B of the seventh optical guard structure 174 may have substantially the same shape as the first optical isolation 170A and the second optical isolation 170B of the sixth optical guard structure 170, respectively. In some embodiments, the first optical isolation 174A and the second optical isolation 174B of the seventh optical guard structure 174 may have sizes greater than the first optical isolation 170A and the second optical isolation 170B of the sixth optical guard structure 170, respectively. In such embodiments, the first to seventh optical guard structures 118, 132 to 136, 168, 170 and 174 may form a continuous structure having tapered sidewalls. In some embodiments, the first optical isolation 174A and the second optical isolation 174B of the seventh optical guard structure 174 may be horizontally offset to the first optical isolation 170A and the second optical isolation 170A of the sixth optical guard structure 170 along the shifting directions as illustrated in FIGS. 8A and 8B. In some embodiments, the seventh optical guard structure 174 are through substrate vias (TSV) completely through the supporting substrate 156 and may be formed by any suitable methods for forming the TSVs. Vias only partially through the supporting substrate 156 may also be used for the seventh optical guard structure 174. As illustrated in FIG. 14, the first optical isolation 174A and the second optical isolation 174B of the seventh optical guard structure 174 have vertical sidewalls, however, the first optical isolation 174A and the second optical isolation 174B of the seventh optical guard structure 174 may each has a tapered shape or reversed tapered shape in a cross-sectional view. In some embodiments, the seventh optical guard structure 174 are omitted so that no features (except impurities) is disposed in the supporting substrate 156.

In some embodiments, any of the first to seventh optical guard structures 118, 132 to 136, 168, 170 and 174 can be omitted according to the requirements of design, manufacturing ability, and/or the manufacturing cost. A longer length, either in a continuous or discontinuous manner, of first to seventh optical guard structures 118, 132 to 136, 168, 170 and 174 can result in better performance of reducing or preventing the optical interference. In some embodiments, over 90% of the light paths (e.g., over 90% of the length OL or thickness T) are laterally surrounded by the structures formed of a combination of any of the first to seventh optical guard structures 118, 132 to 136, 168, 170, and 174 to achieve the optimized performance of reducing the optical interference. In some embodiments, over 50% of the light paths (e.g., over 90% of the length OL or thickness T) are laterally surrounded by the structures formed of a combination of any of the first to seventh optical guard structures 118, 132 to 136, 168, 170, and 174 to balance the performance and manufacturing complexity and cost. In some embodiments, about 10% to about 30% of the light paths (e.g., over 90% of the length OL or thickness T) are laterally surrounded by the structures formed of a combination of any of the first to seventh optical guard structures 118, 132 to 136, 168, 170, and 174 to reduce the manufacturing complexity and cost to a degree but still can have sufficient performance of reducing the optical interference.

Embodiments of the present disclosure provides a photonic package including both optical devices and electrical devices, and the method of forming the same. In particular, the photonic package may include grating couplers as an interface to send or receive optical signals to or from an external photonic device. This disclosure provides an optical guard structure that may be disposed around the light paths directing to the grating couplers, such as between the grating couplers, an interconnect structure of a photonic die, a dummy die, a supporting substrate, or a combination thereof, which may effectively reduce the interference between optical signals. Thus, the photonic package may include an increased density of the grating couplers with reduced optical signal transmission noise.

An embodiment is a package, including a photonic die that includes: a waveguide disposed in a cladding layer; a first grating coupler and a second grating coupler disposed in the cladding layer, wherein the first grating coupler and the second grating coupler have a gap therebetween in a first direction, wherein the first grating coupler has a first end and a second end opposite the first end in a second direction perpendicular to the first direction; a first optical guard structure through the cladding layer and disposed in the gap between the first grating coupler and the second grating coupler, wherein the first optical guard structure extends over the first end and the second end of the first grating coupler in the second direction; and an interconnect structure over the cladding layer, wherein the interconnect structure includes an interconnect disposed in a first dielectric layer and a second dielectric layer; an electronic die including circuits electrically coupled to the interconnect of the interconnect structure; and an insulating layer laterally surrounding the electronic die. In an embodiment, the package further includes a second optical guard structure disposed in the first dielectric layer and a third optical guard structure disposed in the second dielectric layer, wherein the third optical guard structure is disposed over the second optical guard structure, wherein the second optical guard structure and the third optical guard structure overlap the first optical guard structure and the gap between the first grating coupler and the second grating coupler in a plan view. In an embodiment, the package further includes a dummy die disposed in the insulating layer, wherein the dummy die includes a dielectric bonding layer bonded to the second dielectric layer and a fourth optical guard structure disposed in the dielectric bonding layer, wherein the fourth optical guard structure extends over the first end and the second end of the first grating coupler in the second direction and overlaps the gap between the first grating coupler and the second grating coupler in a plan view. In an embodiment, the package further includes a substrate attached to the insulating layer. In an embodiment, the substrate includes a fifth optical guard structure extending over the first end and the second end of the first grating coupler in the second direction and overlapping the gap between the first grating coupler and the second grating coupler in a plan view. In an embodiment, the first optical guard structure includes a first optical isolation and a second optical isolation, wherein a total length of the first optical isolation and the second optical isolation in the second direction is at least 2 times greater than a length of the first grating coupler in the second direction. In an embodiment, the first optical isolation has a first shape enclosing the first grating coupler in a plan view, and the second optical isolation has a second shape enclosing the second grating coupler in the plan view.

Another embodiment is a package, including: a photonic die that includes: a waveguide disposed in a cladding layer; a first grating coupler and a second grating coupler disposed in the cladding layer, wherein the first grating coupler and the second grating coupler have a gap therebetween in a first direction, wherein the first grating coupler has a first end and a second end opposite to the first end in a second direction perpendicular to the first direction; and an interconnect structure over the cladding layer, the interconnect structure including: a first dielectric layer; a second dielectric layer over the first dielectric layer; an interconnect disposed in the first dielectric layer and the second dielectric layer; a first optical guard structure disposed in the first dielectric layer, wherein the first optical guard structure is between the first grating coupler and the second grating coupler and extends over the first end and the second end of the first grating coupler in the second direction in a plan view; and a second optical guard structure disposed in the second dielectric layer and overlapping the first optical guard structure in the plan view; an electronic die disposed over interconnect structure and electrically coupled to the interconnect of the interconnect structure; and an insulating layer laterally surrounding the electronic die. In an embodiment, the second optical guard structure includes a first optical isolation and a second optical isolation extending in the gap, wherein the first optical isolation extends toward the first grating coupler in a portion of the first optical isolation that is beyond the first end of the first grating coupler, and the second optical isolation extends toward the second grating coupler in a portion of the second optical isolation that is beyond the second end of the first grating coupler. In an embodiment, the first optical isolation and the second optical isolation of the first optical guard structure have different shapes in the plan view. In an embodiment, the second optical guard structure includes a third optical isolation over the first optical isolation of the first optical guard structure and a fourth optical isolation over the second optical isolation of the first optical guard structure, wherein the third optical isolation is horizontally more distant away from the second grating coupler than the first optical isolation, and the fourth optical isolation is horizontally more distant away from the first grating coupler than the second optical isolation. In an embodiment, the package further includes a third optical guard structure disposed in the cladding layer and between the first grating coupler and the second grating coupler, wherein the first optical guard structure, the second optical guard structure, and the third optical guard structure form a continuous structure. In an embodiment, the second optical guard structure has a greater size than the first optical guard structure. In an embodiment, the package further includes a dummy die disposed in the insulating layer, wherein the dummy die includes a dielectric bonding layer bonded to the second dielectric layer, a substrate, a third optical guard structure disposed in the substrate, wherein the third optical guard structure extends over the first end and the second end of the first grating coupler in the second direction and overlaps the gap between the first grating coupler and the second grating coupler in the plan view. In an embodiment, the package further includes a supporting substrate attached to the insulating layer, wherein the supporting substrate includes a fourth optical guard structure disposed therein, wherein the fourth optical guard structure extends over the first end and the second end of the first grating coupler in the second direction and overlaps the gap between the first grating coupler and the second grating coupler in the plan view, wherein the fourth optical guard structure is a through via.

A further embodiment is a method for forming a package. The method includes patterning a layer to form a waveguide, a first grating coupler, and a second grating coupler, wherein the first grating coupler and the second grating coupler has a gap therebetween in a first direction, wherein the first grating coupler has a first end and a second end opposite to the first end in a second direction perpendicular to the first direction; forming a cladding layer over the waveguide, the first grating coupler, and the second grating coupler; forming a first optical guard structure between the first grating coupler and the second grating coupler, wherein the first optical guard structure extends over the first end and the second end of the first grating coupler in the second direction; forming an interconnect structure over the cladding layer, wherein the interconnect structure includes an interconnect disposed in a dielectric layer; bonding an electronic die to the interconnect structure; and forming an insulating layer laterally surrounding the electronic die. In an embodiment, the method includes forming a second optical guard structure in the dielectric layer when forming the interconnect, wherein the second optical guard structure overlaps the first optical guard structure and the gap between the first grating coupler and the second grating coupler in a plan view. In an embodiment, the second optical structure in the dielectric layer is formed after the interconnect is formed. In an embodiment, the first optical guard structure includes a first optical isolation and a second optical isolation extending in the gap, wherein the first optical isolation extends toward the first grating coupler in a portion of the first optical isolation that is beyond the first end of the first grating coupler, and the second optical isolation extends toward the second grating coupler in a portion of the second optical isolation that is beyond the second end of the first grating coupler, wherein the first optical isolation and the second optical isolation are formed in same processes. In an embodiment, the method further includes attaching a substrate to the insulating layer, and the method further including forming a third optical guard structure in the substrate after attaching the substrate to the insulating layer, wherein the third optical guard structure overlaps the gap between the first grating coupler and the second grating coupler in a plan view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A package, comprising:
a photonic die comprising:
a waveguide disposed in a cladding layer;
a first grating coupler and a second grating coupler disposed in the cladding layer, wherein the first grating coupler and the second grating coupler have a gap therebetween in a first direction, wherein the first grating coupler has a first end and a second end opposite the first end in a second direction perpendicular to the first direction;
a first optical guard structure through the cladding layer and disposed in the gap between the first grating coupler and the second grating coupler, wherein the first optical guard structure extends over the first end and the second end of the first grating coupler in the second direction; and
an interconnect structure over the cladding layer, wherein the interconnect structure comprises an interconnect disposed in a first dielectric layer and a second dielectric layer;
an electronic die comprising circuits electrically coupled to the interconnect of the interconnect structure; and
an insulating layer laterally surrounding the electronic die.

2. The package of claim 1, further comprising a second optical guard structure disposed in the first dielectric layer and a third optical guard structure disposed in the second dielectric layer, wherein the third optical guard structure is disposed over the second optical guard structure, wherein the second optical guard structure and the third optical guard structure overlap the first optical guard structure and the gap between the first grating coupler and the second grating coupler in a plan view.

3. The package of claim 1, further comprising a dummy die disposed in the insulating layer, wherein the dummy die comprises a dielectric bonding layer bonded to the second dielectric layer and a fourth optical guard structure disposed in the dielectric bonding layer, wherein the fourth optical guard structure extends over the first end and the second end of the first grating coupler in the second direction and overlaps the gap between the first grating coupler and the second grating coupler in a plan view.

4. The package of claim 1, further comprising a substrate attached to the insulating layer.

5. The package of claim 4, wherein the substrate comprises a fifth optical guard structure extending over the first end and the second end of the first grating coupler in the second direction and overlapping the gap between the first grating coupler and the second grating coupler in a plan view.

6. The package of claim 1, wherein the first optical guard structure comprises a first optical isolation and a second optical isolation, wherein a total length of the first optical isolation and the second optical isolation in the second direction is at least 2 times greater than a length of the first grating coupler in the second direction.

7. The package of claim 6, wherein the first optical isolation has a first shape enclosing the first grating coupler in a plan view, and the second optical isolation has a second shape enclosing the second grating coupler in the plan view.

8. A package, comprising:
a photonic die comprising:
a waveguide disposed in a cladding layer;
a first grating coupler and a second grating coupler disposed in the cladding layer, wherein the first grating coupler and the second grating coupler have a gap therebetween in a first direction, wherein the first grating coupler has a first end and a second end opposite to the first end in a second direction perpendicular to the first direction; and
an interconnect structure over the cladding layer, the interconnect structure comprising:
a first dielectric layer;
a second dielectric layer over the first dielectric layer;
an interconnect disposed in the first dielectric layer and the second dielectric layer;
a first optical guard structure disposed in the first dielectric layer, wherein the first optical guard structure is between the first grating coupler and the second grating coupler and extends over the first end and the second end of the first grating coupler in the second direction in a plan view; and
a second optical guard structure disposed in the second dielectric layer and overlapping the first optical guard structure in the plan view;
an electronic die disposed over interconnect structure and electrically coupled to the interconnect of the interconnect structure; and
an insulating layer laterally surrounding the electronic die.

9. The package of claim 8, wherein the second optical guard structure comprises a first optical isolation and a second optical isolation extending in the gap, wherein the first optical isolation extends toward the first grating coupler in a portion of the first optical isolation that is beyond the first end of the first grating coupler, and the second optical isolation extends toward the second grating coupler in a portion of the second optical isolation that is beyond the second end of the first grating coupler.

10. The package of claim 9, wherein the first optical isolation and the second optical isolation of the first optical guard structure have different shapes in the plan view.

11. The package of claim 10, wherein the second optical guard structure comprises a third optical isolation over the first optical isolation of the first optical guard structure and a fourth optical isolation over the second optical isolation of the first optical guard structure, wherein the third optical isolation is horizontally more distant away from the second grating coupler than the first optical isolation, and the fourth optical isolation is horizontally more distant away from the first grating coupler than the second optical isolation.

12. The package of claim 9, further comprising a third optical guard structure disposed in the cladding layer and between the first grating coupler and the second grating coupler, wherein the first optical guard structure, the second optical guard structure, and the third optical guard structure form a continuous structure.

13. The package of claim 8, wherein the second optical guard structure has a greater size than the first optical guard structure.

14. The package of claim 8, further comprising a dummy die disposed in the insulating layer, wherein the dummy die comprises a dielectric bonding layer bonded to the second dielectric layer, a substrate, a third optical guard structure disposed in the substrate, wherein the third optical guard structure extends over the first end and the second end of the first grating coupler in the second direction and overlaps the gap between the first grating coupler and the second grating coupler in the plan view.

15. The package of claim 14, further comprising a supporting substrate attached to the insulating layer, wherein the supporting substrate comprises a fourth optical guard structure disposed therein, wherein the fourth optical guard structure extends over the first end and the second end of the first grating coupler in the second direction and overlaps the gap between the first grating coupler and the second grating coupler in the plan view, wherein the fourth optical guard structure is a through via.

16. A method for forming a package, comprising:
patterning a layer to form a waveguide, a first grating coupler and a second grating coupler, wherein the first grating coupler and the second grating coupler has a gap therebetween in a first direction, wherein the first grating coupler has a first end and a second end opposite to the first end in a second direction perpendicular to the first direction;
forming a cladding layer over the waveguide, the first grating coupler, and the second grating coupler;
forming a first optical guard structure between the first grating coupler and the second grating coupler, wherein the first optical guard structure extends over the first end and the second end of the first grating coupler in the second direction;
forming an interconnect structure over the cladding layer, wherein the interconnect structure comprises an interconnect disposed in a dielectric layer;
bonding an electronic die to the interconnect structure; and
forming an insulating layer laterally surrounding the electronic die.

17. The method of claim 16, further comprising forming a second optical guard structure in the dielectric layer when forming the interconnect, wherein the second optical guard structure overlaps the first optical guard structure and the gap between the first grating coupler and the second grating coupler in a plan view.

18. The method of claim 17, wherein the second optical structure in the dielectric layer is formed after the interconnect is formed.

19. The method of claim 16, wherein the first optical guard structure comprises a first optical isolation and a second optical isolation extending in the gap, wherein the first optical isolation extends toward the first grating coupler in a portion of the first optical isolation that is beyond the first end of the first grating coupler, and the second optical isolation extends toward the second grating coupler in a portion of the second optical isolation that is beyond the second end of the first grating coupler, wherein the first optical isolation and the second optical isolation are formed in same processes.

20. The method of claim 16, further comprising attaching a substrate to the insulating layer, and the method further comprising forming a third optical guard structure in the substrate after attaching the substrate to the insulating layer, wherein the third optical guard structure overlaps the gap between the first grating coupler and the second grating coupler in a plan view.
